(19) United States
(12) Patent Application Publication
(10) Pub. No.: US 2013/0320425 A1
(43) Pub. Date: Dec. 5, 2013

(54) NONVOLATILE SEMICONDUCTOR MEMORY DEVICE

(71) Applicant: KABUSHIKI KAISHA TOSHIBA, Minato-ku (JP)

(72) Inventor: Naoki YASUDA, Yokkaichi-shi (JP)

(21) Appl. No.: 13/906,969

(22) Filed: May 31, 2013

(30) Foreign Application Priority Data
May 31, 2012 (JP) 2012-125391
May 27, 2013 (JP) 2013-111256

(51) Int. Cl. H01L 29/792

(52) U.S. Cl. CPC H01L 29/792
USPC 257/324

(57) ABSTRACT

According to one embodiment, a nonvolatile semiconductor memory device comprises a semiconductor substrate, conductive layers and insulating layers alternately stacked above the semiconductor substrate, a block insulating layer which is formed on an inner surface of a hole formed in the conductive layers and the insulating layers and extending in a stacking direction, a charge storage layer formed on the block insulating layer, a tunnel insulating layer formed on the charge storage layer, and a semiconductor layer formed on the tunnel insulating layer. Letting R₁ be a distance from a central axis of the hole to an interface between the semiconductor layer and the tunnel insulating layer, and R₂ be a distance from the central axis of the hole to an interface between the charge storage layer and the block insulating layer, an expression (3) below holds:

$$4.8 [ nm ] < {R}_{1} ln ( \frac{{R}_{2}}{{R}_{1}} ) < 8.8 [ nm ] \qquad ( 3 )$$

### CROSS-REFERENCE TO RELATED APPLICATIONS

This application is based upon and claims the benefit of priority from Japanese Patent Applications No. 2012-125391, filed May 31, 2012; and No. 2013-111256, filed May 27, 2013, the entire contents of all of which are incorporated herein by reference.

### FIELD

Embodiments described herein relate generally to a nonvolatile semiconductor memory device.

### BACKGROUND

A three-dimensionally stacked memory multilayered in the vertical direction and formed by collective processing in order to suppress the increase in process cost has been proposed as a NAND flash memory.

In this three-dimensionally stacked memory, cylindrical memory hole is formed through a plurality of electrodes stacked on a semiconductor substrate at once, and a memory film is formed on the inner wall of the memory hole. After that, polysilicon (a silicon pillar) serving as a channel is formed inside the memory hole. Consequently, a NAND string (memory string) including a plurality of MONOS memory cells connected in series in the stacking direction can be formed at once. It is also possible to achieve a memory capacity higher than that of the conventional floating gate type NAND flash memory.

In the collectively processed, three-dimensionally stacked memory described above, however, the MONOS structure is formed by burying an insulating layer in the interior of the memory hole. Accordingly, the tunnel insulating layer must be a deposition film. Generally, many trap levels are formed in a deposition film. If write/erase operations (cycling) are repetitively performed by using a deposition film like this, the data retention characteristic deteriorates after that.

### BRIEF DESCRIPTION OF THE DRAWINGS

FIG. 1 is a perspective view showing an example of the overall configuration of a nonvolatile semiconductor memory device according to an embodiment;

FIG. 2 is a perspective view showing a NAND string according to the embodiment;

FIG. 3 is an enlarged sectional view of the NAND string shown in FIG. 2;

FIG. 4 is a circuit diagram showing the NAND string shown in FIG. 2;

FIG. 5 is a sectional view showing a MONOS memory cell having a first structure according to the embodiment;

FIG. 6 is a plan view showing the MONOS memory cell having the first structure according to the embodiment;

FIG. 7 is a sectional view showing a MONOS memory cell having a second structure according to the embodiment;

FIG. 8 is a plan view showing the MONOS memory cell having the second structure according to the embodiment;

FIG. 9 is a view showing positive hole current and electron current injected in the MONOS memory cell having the first structure according to the embodiment;

FIG. 10 is a view showing positive hole current and electron current injected in the MONOS memory cell having the second structure according to the embodiment;

FIG. 11 is a developed view of an interface between a charge storage layer and block insulating layer in the MONOS memory cell according to the embodiment;

FIG. 12 is a graph showing the relationship between an applied voltage Vₒₓ and trap generation amount Nt in a silicon oxide monolayered film relevant to the embodiment;

FIG. 13 is a view showing an energy band when a voltage is applied to a MOS transistor relevant to the embodiment;

FIG. 14 is a view showing an energy band when a voltage is applied to the MONOS memory cell according to the embodiment;

FIG. 15 is a graph showing the relationship between R₁ ln(R₂/R₁) and R₂ in the MONOS memory cell according to the embodiment;

FIG. 16 is a graph showing the relationship between R₁ ln(R₂/R₁) and R₂ in the MONOS memory cell according to the embodiment; and

FIG. 17 is an enlarged sectional view of Example 2 of the MONOS memory cell according to the embodiment.

### DETAILED DESCRIPTION

In general, according to one embodiment, a nonvolatile semiconductor memory device includes a semiconductor substrate, a plurality of conductive layers and a plurality of insulating layers alternately stacked on the semiconductor substrate, a block insulating layer which is formed on an inner surface of a hole formed in the plurality of conductive layers and the plurality of insulating layers and extending in a stacking direction, and has a silicon oxide interface with respect to the plurality of conductive layers, a charge storage layer formed on the block insulating layer, a tunnel insulating layer formed on the charge storage layer, and a semiconductor layer formed on the tunnel insulating layer. Letting R₁ be a distance from a central axis of the hole to an interface between the semiconductor layer and the tunnel insulating layer, R₂ be a distance from the central axis of the hole to an interface between the charge storage layer and the block insulating layer, R₃ be a distance from the central axis of the hole to the interface between the block insulating layer and the conductive layer, and L be a thickness of the conductive layer in the stacking direction, expressions (1) to (3) below hold:

$$\begin{matrix}\frac{{R}_{3}}{{R}_{1}} > 1.4 & ( 1 ) \\ {R}_{2} L > 1.6 \times {10}^{- 12} [ {cm}^{2} ] & ( 2 ) \\ 4.8 [ nm ] < {R}_{1} ln ( \frac{{R}_{2}}{{R}_{1}} ) < 8.8 [ nm ] & ( 3 )\end{matrix}$$

This embodiment will be explained below with reference to the accompanying drawings. In the following drawings, the same reference numerals denote the same parts. Also, a repetitive explanation will be made as needed.

### <Overall Configuration Example>

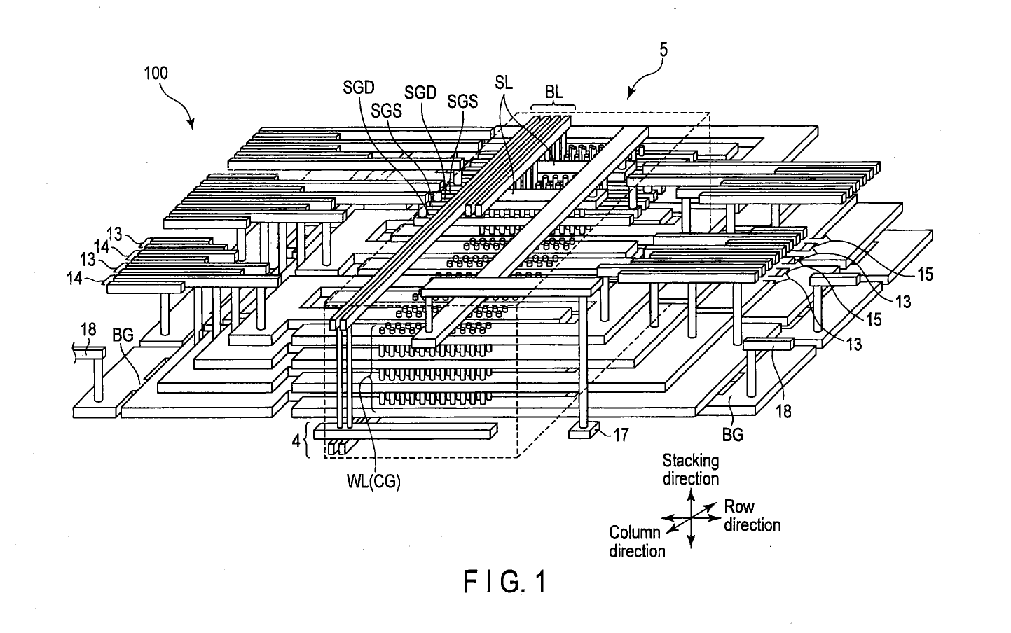

First, an example of the overall configuration of a nonvolatile semiconductor memory device according to the embodiment will be explained with reference to FIG. 1.

FIG. 1 is a perspective view showing the overall configuration example of the nonvolatile semiconductor memory device according to this embodiment.

As shown in FIG. 1, a memory cell array 5 includes a plurality of word lines WL (control gates CG), a plurality of bit lines BL, a plurality of source lines SL, a plurality of backgates BG, a plurality of source-side selection gates SGS, and a plurality of drain-side selection gates SGD.

In the memory cell array 5, memory cell transistors MTr for storing data are arranged at the intersections of the plurality of stacked word lines WL and silicon pillars SP (to be described later). A plurality of memory cell transistors MTr connected in series along the silicon pillar SP form a NAND string (to be described later).

The end portions of the plurality of stacked word lines WL in the row direction form a stepped shape, and a contact is connected to the upper surface of each step. The upper portions of these contacts are connected to interconnections. In the column direction, even-numbered control gates CG are connected to each other at one end in the row direction, and odd-numbered control gates CG are connected to each other at the other end in the row direction. Note that FIG. 1 shows an example in which four layers of the word lines WL are stacked, but the present embodiment is not limited to this.

Also, contacts are connected to the upper surfaces of the end portions of the source lines SL, backgates BG, source-side selection gates SGS, and drain-side selection gates SGD in the row direction. Interconnections are connected in the upper portions of the contacts.

A word line driver 13 is connected to the word lines WL via the interconnections formed in the upper portions and the contacts.

A source-side selection gate line driver 14 is connected to the source-side selection gates SGS via the interconnections formed in the upper portions and the contacts.

A drain-side selection gate line driver 15 is connected to the drain-side selection gates SGD via the interconnections formed in the upper portions and the contacts.

A backgate driver 18 is connected to the backgates BG via the interconnections formed in the upper portions and the contacts.

A plurality of source line drivers 17 are connected to the source lines SL via the interconnections formed in the upper portions and the contacts. The source line drivers 17 are each connected to a predetermined number of source lines SL, and are independently controlled by a control circuit 10.

A sense amplifier 4 is connected via contacts connected to the lower ends of the end portions of the bit lines BL in the column direction.

Note that all interconnections connected to the various drivers are formed in an interconnection layer on the same level in FIG. 1, but the present invention is not limited to this, and these interconnections may also be formed in interconnection layers on different levels. Note also that the number of drivers is determined in accordance with the number of gates, but one driver can be connected to either one gate or a predetermined number of gates.

### <Configuration Example of NAND String>

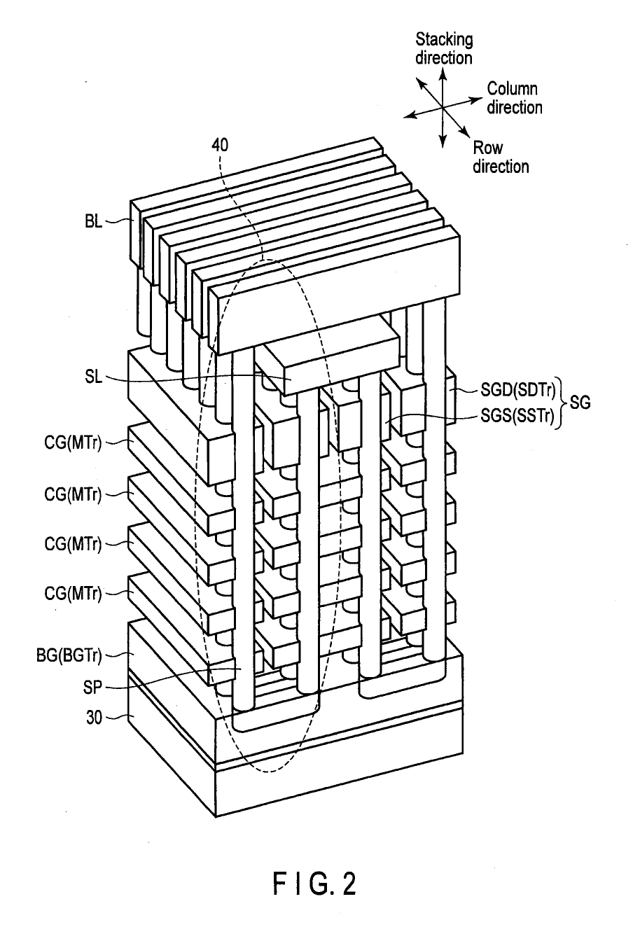

Next, a configuration example of a NAND string 40 according to this embodiment will be explained with reference to FIGS. 2, 3, and 4.

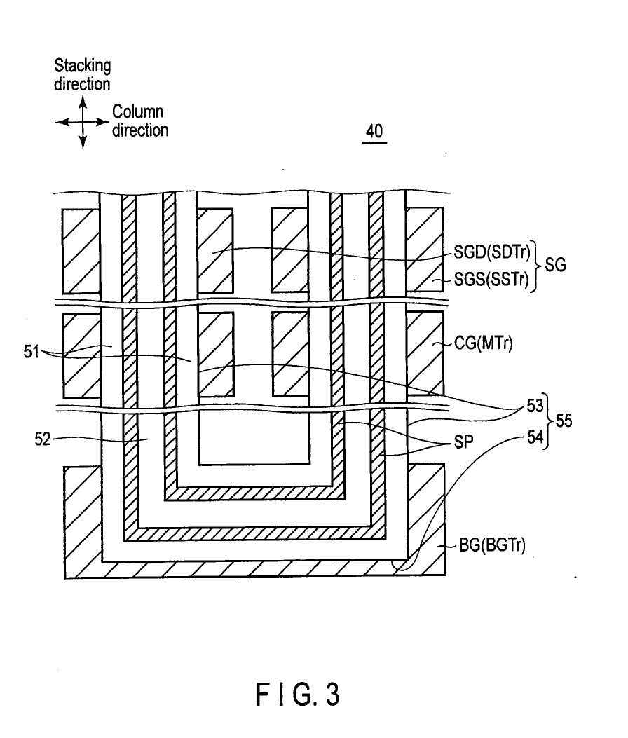

FIG. 2 is a perspective view showing the NAND string 40 according to this embodiment. FIG. 3 is an enlarged sectional view of the NAND string 40 shown in FIG. 2. Note that a memory film 51 (to be described later) is not illustrated in FIG. 2.

In the memory cell array 5 as shown in FIGS. 2 and 3, the NAND string 40 is formed above a semiconductor substrate 30, and includes the backgate BG, a plurality of control gates CG, the selection gate SG, the U-shaped silicon pillar (semiconductor layer) SP, and the memory film 51.

The backgate BG is formed on an insulating layer (not shown) on the semiconductor substrate 30. The backgate BG is formed to two-dimensionally spread. The backgate BG is formed by a conductive layer made of, e.g., polysilicon (poly-Si) in which an impurity (e.g., phosphorus) is doped.

The plurality of control gates CG are formed on the backgate BG with inter-electrode insulating layers 64 (to be described later) being interposed between them. In other words, the plurality of inter-electrode insulating layers 64 and the plurality of control gates CG are alternately stacked on the backgate BG. The control gate CG is made of, e.g., poly-Si in which an impurity (e.g., boron) is doped, or a conductive layer such as a metal.

The selection gate SG is formed on an insulating layer (not shown) on the uppermost control gate CG. Like the control gate CG, the selection gate SG is made of impurity-doped poly-Si or a conductive layer such as a metal.

The source line SL is formed above the selection gate SG with an insulating layer (not shown) being interposed between them, and the bit lines BL are formed above the source line SL with an insulating layer (not shown) being interposed between them.

A U-shaped memory hole 55 is formed in the selection SG, control gates CG, backgate BG, and inter-electrode insulating layers 64. The U-shaped memory hole 55 includes a pair of through holes 53 juxtaposed in the column direction, and a connecting hole 54 for connecting the lower ends of the pair of through holes 53. The through holes 53 are formed to extend in the stacking direction in the selection gate SG, control gates CG, and inter-electrode insulating layers 64. The connecting hole 54 is formed to extend in the column direction in the backgate BG.

Also, a slit (not shown) expanding in the row direction and stacking direction between the pair of through holes 53 is formed in the control gates CG and inter-electrode insulating layers 64. This slit divides the control gates CG and inter-electrode insulating layers 64 along the row direction. In addition, an opening (not shown) expanding in the row direction and stacking direction is formed in the selection gate SG above the slit so as to open it. This opening divides the selection gate SG along the row direction: one is the drain-side selection gate SGD, and the other is the source-side selection gate SGS. An insulating material or the like is buried in the slit and opening.

The memory film 51 is formed on the inner surfaces of the U-shaped memory hole 55. That is, the memory film 51 is formed on the selection gate SG, control gates CG, backgate BG, and inter-electrode insulating layers 64 in the U-shaped memory hole 55. Details of the arrangement of the memory film 51 according to this embodiment will be described later.

The silicon pillar SP is formed on the memory film 51 in the U-shaped memory hole 55. That is, the silicon pillar SP includes a pair of pillar portions formed on the memory film 51 in the pair of through holes 53, and a connecting portion formed on the memory film 51 in the connecting hole 54. The silicon pillar SP is formed by a conductive layer made of, e.g., poly-Si containing an impurity (e.g., phosphorus) or amorphous silicon (a-Si), and functions as a channel.

A core layer 52 is formed on the silicon pillar SP in the U-shaped memory hole 55. The core layer 52 is formed by an insulating layer made of, e.g., silicon oxide (e.g., SiO₂), and filled in the U-shaped memory hole 55. Note that it is also possible to form a hollow instead of the core layer 52, and leave the U-shaped memory hole 55 unfilled.

Note also that although not shown, those portions of the selection gate SG and control gates CG, which are in contact with the insulating material (slit and opening), can also be silicidized.

The silicon pillar SP and the memory film 51 and various gates formed around the silicon pillar SP form various transistors. The NAND string 40 is formed along the silicon pillar SP by using it as a channel.

More specifically, the control gate CG, the silicon pillar SP, and the memory film 51 formed between them form the memory cell transistor MTr. Also, the selection gates SG (the drain-side selection gate SGD and source-side selection gate SGS), the silicon pillar SP, and the memory film 51 formed between them form selection transistors (a drain-side selection transistor SDTr and source-side selection transistor SSTr).

Furthermore, the backgate BG, the silicon pillar SP, and the memory film 51 formed between them form a backgate transistor BGTr. A voltage is applied to the backgate BG so that the backgate transistor BGTr is normally ON.

Note that in the selection transistors and backgate transistor BGTr, the memory film 51 does not store data but simply functions as a gate insulating film regardless of its name “memory film”.

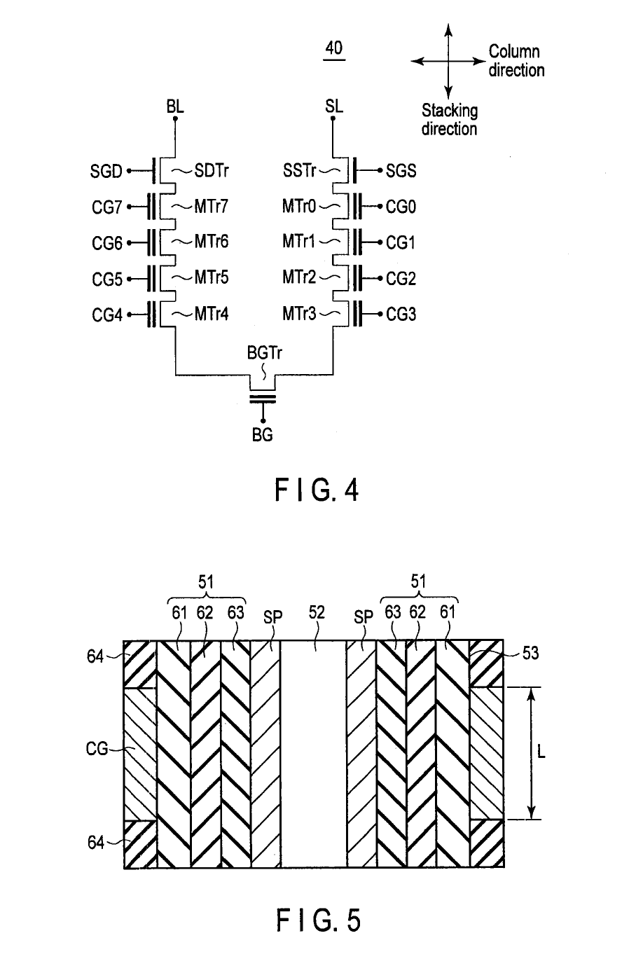

FIG. 4 is a circuit diagram showing the NAND string 40 shown in FIG. 2.

As shown in FIG. 4, the NAND string 40 includes the source-side selection transistor SSTr, the drain-side selection transistor SDTr, memory cell transistors MTr0 to MTr7, and the backgate transistor BGTr.

As described previously, the current paths of the memory cell transistors MTr0 to MTr7 are connected in series between the source-side selection transistor SSTr and drain-side selection transistor SDTr. The current path of the backgate transistor BGTr is connected in series between the memory cell transistors MTr3 and MTr4.

More specifically, the current paths of the memory cell transistors MTr0 to MTr3 and the current paths of the memory cell transistors MTr4 to MTr7 are respectively connected in series in the stacking direction. These current paths are connected in series by forming the backgate transistor BGTr between the memory cell transistors MTr3 and MTr4 in the lower portion in the stacking direction. That is, the current paths of the source-side selection transistor SSTr, drain-side selection transistor SDTr, memory cell transistors MTr0 to MTr7, and backgate transistor BGTr are connected in series as the NAND string 40 along the silicon pillar SP shown in FIG. 2. In a data write operation and data read operation, the backgate transistor BGTr is normally ON.

Also, the control gates of the memory cell transistors MTr0 to MTr7 are connected to control gates CG0 to CG7, and the control gate of the backgate transistor BGTr is connected to the backgate BG. Furthermore, the gate of the source-side selection transistor SSTr is connected to the source-side selection gate SGS, and the gate of the drain-side selection transistor SDTr is connected to the drain-side selection gate SGD.

### <Arrangement of MONOS Memory Cell>

The arrangement of the memory cell transistor MTr (a MONOS memory cell) according to this embodiment will be explained below with reference to FIGS. 5, 6, 7, and 8.

The MONOS memory cell according to this embodiment has a cylindrical shape, and secures the erase characteristic, reduces the variation in data retention characteristic, and suppresses the deterioration of the data retention characteristic caused by repetitive write/erase by defining the radius of the through hole 53, the thicknesses of various layers of the memory film 51, and the thickness of the control gate CG. The MONOS memory cell according to this embodiment will be explained in detail below.

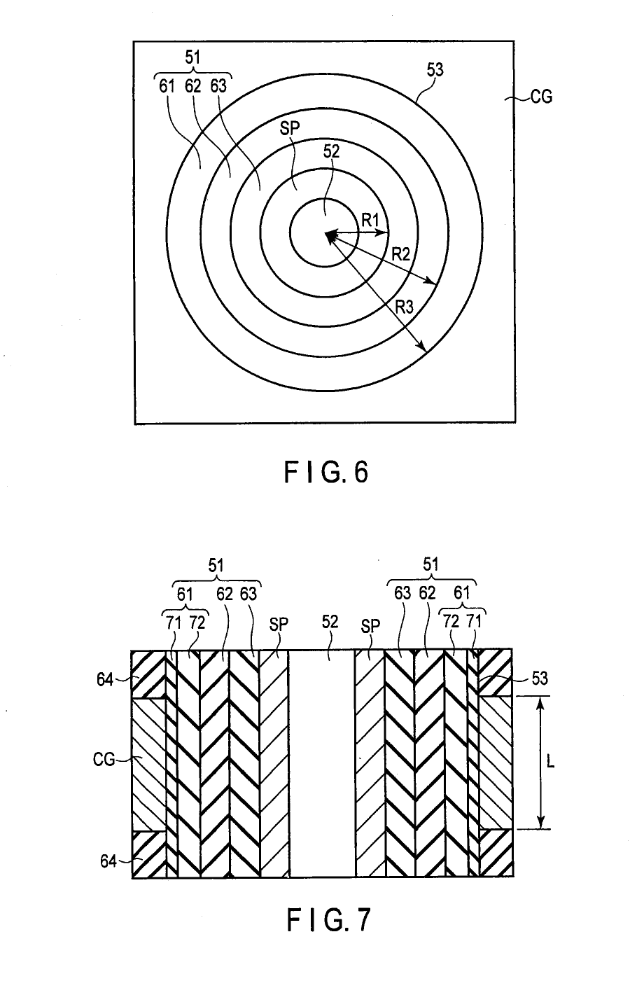

FIG. 5 is a sectional view showing a MONOS memory cell having a first structure according to this embodiment. FIG. 6 is a plan view showing the MONOS memory cell having the first structure according to this embodiment.

As shown in FIGS. 5 and 6, the MONOS memory cell having the first structure includes the control gate CG, memory film 51, and silicon pillar SP.

The control gate CG is positioned between the inter-electrode insulating layers 64 in the stacking direction. The cylindrical through hole 53 is formed to extend through the control gate CG and inter-electrode insulating layers 64 from the upper surface to the lower surface.

The memory film 51 is formed on the inner surface of the through hole 53, and includes a block insulating layer 61, charge storage layer 62, and tunnel insulating layer 63.

The block insulating layer 61 is formed on the inner surface of the through hole 53, i.e., on the side surfaces of the control gate CG and inter-electrode insulating layer 64 in the through hole 53. The charge storage layer 62 is formed on the side surface of the block insulating layer 61 in the through hole 53. The tunnel insulating layer 63 is formed on the side surface of the charge storage layer 62 in the through hole 53.

In the cylindrical MONOS memory cell, the electric flux line spreads and an electric field relaxes from the central axis of the through hole 53 toward the outer circumference. That is, an electric field applied to the tunnel insulating layer 63 close to the central axis is large, but an electric field applied to the block insulating layer 61 far from the central axis is small.

In the cylindrical MONOS memory cell having the first structure, therefore, the block insulating layer 61 need not include a high-k insulating film. Instead, the block insulating layer 61 of the first structure is formed by, e.g., a multilayered film containing silicon oxide, silicon nitride (e.g., SiN), and silicon oxide formed in this order on the side surface of the control gate CG. Note that the block insulating layer 61 is not limited to this, and may also be formed by a monolayered film of silicon oxide. That is, in the first structure, that surface of the block insulating layer 61 which is in contact with the control gate CG is made of silicon oxide.

The charge storage layer 62 is formed by, e.g., a monolayered film of silicon nitride. The tunnel insulating layer 63 is formed by, e.g., a monolayered film of silicon oxide or silicon oxynitride. However, the tunnel insulating layer 63 is not limited to this, and may also be formed by a multilayered film containing silicon oxide, silicon nitride, and silicon oxide.

The silicon pillar SP is formed on the side surface of the tunnel insulating layer 63 in the through hole 53. The core layer 52 is formed inside the silicon pillar SP (i.e., in the center of the through hole 53).

The block insulating layer 61, charge storage layer 62, tunnel insulating layer 63, and silicon pillar SP are formed into a cylindrical shape because they are formed along the cylindrical through hole 53. Also, the block insulating layer 61, charge storage layer 62, tunnel insulating layer 63, and silicon pillar SP are concentrically formed around the central axis of the through hole 53.

In the MONOS memory cell having the first structure according to this embodiment, the relations of expressions (1) to (3) below hold:

$$\begin{matrix}\frac{{R}_{3}}{{R}_{1}} > 1.4 & ( 1 ) \\ {R}_{2} L > 1.6 \times {10}^{- 12} [ {cm}^{2} ] & ( 2 ) \\ 4.8 [ nm ] < {R}_{1} ln ( \frac{{R}_{2}}{{R}_{1}} ) < 8.8 [ nm ] & ( 3 )\end{matrix}$$

where R₁ indicates the distance from the central axis of the through hole 53 to the interface between the silicon pillar SP and tunnel insulating layer 63 (i.e., the outer radius of the silicon pillar SP and the inner radius of the tunnel insulating layer 63), R₂ indicates the distance from the central axis to the interface between the charge storage layer 62 and block insulating layer 61 (i.e., the outer radius of the charge storage layer 62 and the inner radius of the block insulating layer 61), R₃ indicates the distance from the central axis to the interface between the block insulating layer 61 and control gate CG (i.e., the outer radius of the block insulating layer 61 and the radius of the through hole 53), and L indicates the thickness of the control gate CG in the stacking direction. Note that R₃>R₂>R₁>0. The upper limit of R₃ is not restricted from a physical viewpoint, but is desirably about 60 nm or less in order to use this memory cell as a memory cell for future generations.

In the MONOS memory cell having the first structure, (a) the erase characteristic can be ensured because the relation of expression (1) holds, (b) the variation in data retention characteristic can be reduced because the relation of expression (2) holds, and (c) the deterioration of the data retention characteristic caused by repetitive write/erase can be suppressed because the relation of expression (3) holds. The principles of (a) to (c) will be described later.

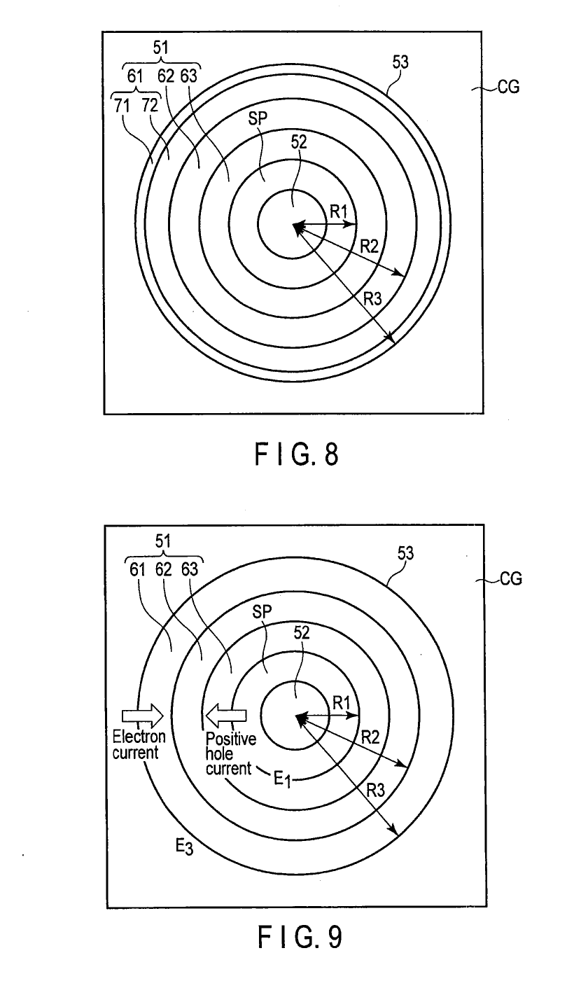

FIG. 7 is a sectional view showing a MONOS memory cell having a second structure according to this embodiment. FIG. 8 is a plan view showing the MONOS memory cell having the second structure according to this embodiment. In the second structure, an explanation of the same features as those of the abovementioned first structure will be omitted, and different points will mainly be explained.

As shown in FIGS. 7 and 8, the second structure differs from the first structure in that the block insulating layer 61 has a cap layer 71.

More specifically, the MONOS memory cell having the second structure includes the block insulating layer 61 including the cap layer 71 and a first layer 72. The cap layer 71 is formed on the inner surface of the through hole 53, i.e., on the side surfaces of the control gate CG and inter-electrode insulating layer 64 in the through hole 53. The first layer 72 is formed on the side surface of the cap layer 71 in the through hole 53. In other words, the cap layer 71 is formed between the first layer 72 and control gate CG.

The first layer 72 is formed by, e.g., a multilayered film containing silicon oxide, silicon nitride, and silicon oxide formed in this order on the side surface of the cap layer 71. Note that the first layer 72 is not limited to this, and may also be formed by a monolayered film of silicon oxide. That is, the first layer has the same structure as that of the block insulating layer 61 in the first structure. The cap layer 71 is made of, e.g., silicon nitride. In the second structure, therefore, that surface of the block insulating layer 61 which is in contact with the control gate CG is made of silicon nitride.

The cap layer 71 made of silicon nitride suppresses the diffusion of a dopant impurity from the control gate CG made of poly-Si to the block insulating layer 61, and prevents a reaction between the control gate CG made of a metal and the block insulating layer 61. The cap layer 71 also suppresses the injection of electrons from the control gate CG during an erase operation.

In the MONOS memory cell having the second structure according to this embodiment, the relation of expression (4) below and the relations of above-described expressions (2) and (3) hold:

$$\frac{{R}_{3}}{{R}_{1}} > 1.8 \qquad ( 4 )$$

where R₃ indicates the distance from the central axis to the interface between the block insulating layer 61 (the cap layer 71) and control gate CG (i.e., the outer radius of the block insulating layer 61 (the cap layer 71) and the radius of the through hole 53). Expression (4) is obtained by the same principle as that of expression (1). In the second embodiment, however, the cap layer 71 made of silicon nitride is formed as the outer circumference of the block insulating layer 61. Consequently, expression (4) in the second structure partly differs from expression (1) in the first structure. This will be described in detail later.

In the MONOS memory cell having the second structure, (a) the erase characteristic can be ensured because the relation of expression (4) holds, (b) the variation in data retention characteristic can be reduced because the relation of expression (2) holds, and (c) the deterioration of the data retention characteristic caused by repetitive write/erase can be suppressed because the relation of expression (3) holds.

### [Principle of (a) (Expressions (1) and (4))]

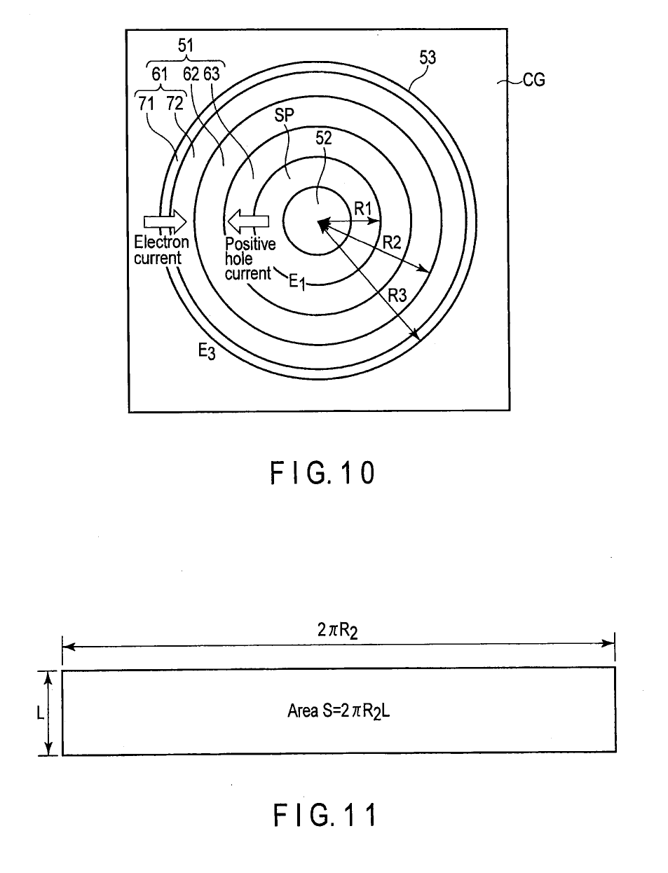

The principle of securing the erase characteristic of the MONOS memory cell according to this embodiment will now be explained with reference to FIGS. 9 and 10.

FIG. 9 is a view showing positive hole current and electron current injected in the MONOS memory cell having the first structure according to this embodiment.

As shown in FIG. 9, in the final stage of an erase operation in the first structure (i.e., at the end of the erase operation), the positive hole current is injected into the tunnel insulating layer 63 from the channel region (silicon pillar SP), and the electron current is injected into the block insulating layer 61 from the control gate CG.

In the MONOS memory cell, an erase operation is performed by injecting positive holes into the charge storage layer 62 from the channel region via the tunnel insulating layer 63. To ensure the erase characteristic, therefore, the positive hole current injected into the tunnel insulating layer 63 from the channel region must be larger than the electron current injected into the block insulating layer 61 from the control gate CG, even in the final stage of the erase operation.

In the final stage of the erase operation in the cylindrical stacked MONOS memory cell, a deeply erased state (positively charged state) is not used in many cases. This is so because the charge storage layer 62 is continuously formed along the stacking direction in the cylindrical stacked MONOS memory cell. That is, the charge storage layer 62 is continuously formed between memory cells adjacent to each other along the stacking direction. Accordingly, positive holes stored in the charge storage layer 62 by the erase operation readily diffuse in the stacking direction because they have a high mobility in silicon nitride, so positive holes move between adjacent memory cells. By taking this into account, a charge neutral state is assumed as the final stage of the erase operation in this embodiment.

In the charge neutral state, positive hole injection from the channel region and electron injection from the control gate CG are represented by expression (5), i.e., represented by the form of FN (Fowler-Nordheim) tunnel current J_{FN}:

$${J}_{FN} ∝ exp ( - \frac{c \sqrt{m} {φ}^{3 / 2}}{E} ) \qquad ( 5 )$$

where c indicates a constant, m indicates a tunneling effective mass, φ indicates a barrier height, and E indicates an electric field (the tunnel effective mass is described in literature 1 “H. Bachhofer, H. Reisinger, E. Bertagnolli, and H. von Philipsborn, “Transient conduction in multidielectric silicon-oxide-nitride-oxide semiconductor structures”, J. Appl. Phys. 89, 2791 (2001)”).

When the MONOS memory cell having the first structure is in the charge neutral state (when the control gate CG is in contact with silicon oxide of the block insulating layer 61), expression (6) holds under the condition that the positive hole current is larger than the electron current by using expression (5):

$$\frac{\sqrt{0.5 {m}_{0}} {( 3.2 )}^{3 / 2}}{{E}_{3}} > \frac{\sqrt{0.6 {m}_{0}} {( 3.8 )}^{3 / 2}}{{E}_{1}} \qquad ( 6 )$$

where m₀ indicates the mass of a free electron, 0.5 m₀ indicates an effective mass when an electron tunnels through silicon oxide (the block insulating layer 61), 3.2 eV indicates a conduction band offset (a barrier height against electrons) between silicon (the control gate CG) and silicon oxide (the block insulating layer 61), 0.6 m₀ indicates an effective mass when a positive hole tunnels through silicon oxide (the tunnel insulating layer 63), 3.8 eV indicates a valence band offset (a barrier height against positive holes) between silicon (the silicon pillar SP) and silicon oxide (the tunnel insulating layer 63), E₁ indicates an electric field on the side of the tunnel insulating layer 63 at the distance R₁ from the central axis, and E₃ indicates an electric field on the side of the block insulating layer 61 at the distance R₃ from the central axis.

On the other hand, expression (7) holds from the condition of charge density conservation:

E₃R₃=E₁R₁ (7)

From expressions (6) and (7) above, expression (8) is obtained for R₁ and R₃:

$$\frac{{R}_{3}}{{R}_{1}} > \sqrt{\frac{0.6}{0.5}} {( \frac{3.8}{3.2} )}^{3 / 2} = 1.4 \qquad ( 8 )$$

As described above, in the MONOS memory cell having the first structure according to this embodiment, R₁ and R₃ satisfy the relation of expression (1) described earlier in order to (a) secure the erase characteristic.

FIG. 10 is a view showing positive hole current and electron current injected in the MONOS memory cell having the second structure according to this embodiment.

As shown in FIG. 10, in the final stage of an erase operation in the second structure (i.e., at the end of the erase operation), the positive hole current is injected into the tunnel insulating layer 63 from the channel region (silicon pillar SP), and the electron current is injected into the block insulating layer 61 (the cap layer 71) from the control gate CG.

To ensure the erase characteristic in the second structure, as in the first structure, the positive hole current injected into the tunnel insulating layer 63 from the channel region must be larger than the electron current injected into the block insulating layer 61 from the control gate CG, even in the final stage of the erase operation.

When the MONOS memory cell having the second structure is in the charge neutral state (when the control gate CG is in contact with silicon nitride of the block insulating layer 61 (the cap layer 71)), expression (9) holds under the condition that the positive hole current is larger than the electron current by using expression (5):

$$\frac{\sqrt{0.27 {m}_{0}} {( 2.2 )}^{3 / 2}}{{E}_{3}} > \frac{\sqrt{0.6 {m}_{0}} {( 3.8 )}^{3 / 2}}{{E}_{1}} \qquad ( 9 )$$

where 0.27 m₀ indicates an effective mass when an electron tunnels through silicon nitride (the block insulating layer 61), 2.2 eV indicates a conduction band offset (a barrier height against electrons) between silicon (the control gate CG) and silicon nitride (the block insulating layer 61), 0.6 m₀ indicates an effective mass when a positive hole tunnels through silicon oxide (the tunnel insulating layer 63), and 3.8 eV indicates a valence band offset (a barrier height against positive holes) between silicon (the silicon pillar SP) and silicon oxide (the tunnel insulating layer 63).

On the other hand, expression (10) holds from the condition of charge density conservation:

7.4E₃R₃=3.9E₁R₁ (10)

where 7.4 indicates the dielectric constant of silicon nitride, and 3.9 indicates that of silicon oxide. From expressions (9) and (10) above, expression (11) is obtained for R₁ and R₂:

$$\frac{{R}_{3}}{{R}_{1}} > \frac{3.9}{7.4} \sqrt{\frac{0.6}{0.27}} {( \frac{3.8}{2.2} )}^{3 / 2} = 1.8 \qquad ( 11 )$$

As described above, in the MONOS memory cell having the second structure according to this embodiment, R₁ and R₂ satisfy the relation of expression (4) described earlier in order to (a) secure the erase characteristic.

### [Principle of (b) (Expression (2))]

Next, the principle of reducing the variation in data retention characteristic of the MONOS memory cell according to this embodiment will be explained with reference to FIG. 11. Note that the principle of (b) similarly applies to the first and second structures, so the following explanation does not particularly distinguish between them.

FIG. 11 is a developed view of the interface between the charge storage layer 62 and block insulating layer 61 in the MONOS memory cell according to this embodiment.

In the MONOS memory cell, electrons/positive holes are mainly trapped in the interface between the charge storage layer 62 (silicon nitride) and block insulating layer 61 (silicon oxide) in write/erase. That is, as shown in FIG. 11, letting L be the thickness (gate length) of the control gate CG in the stacking direction, an area S of this interface capable of trapping electric charge in one MONOS memory cell is represented by expression (12) below:

S=2πR₂L (12)

Also, letting Nₜᵣₐₚ be the trap density, a trapped charge count (trap count) N contained in this region is represented by expression (13) below:

N=S×Nₜᵣₐₚ=2πR₂L×Nₜᵣₐₚ (13)

In an actual MONOS memory cell, it is presumably possible to reduce R₂ to, e.g., about 10 nm. Also, it is perhaps possible to reduce L to, e.g., about 10 nm. In the charge storage layer 62, Nₜᵣₐₚ is about 1×10¹³ cm⁻². When micropatterning advances, therefore, the trap count N contained in the area S probably reduces to about 63 in accordance with expression (13).

When the trap count N in the charge storage layer 62 decreases, the variation in retention time defined as a time required for a threshold voltage reduction amount ΔVₜₕ to reach a predetermined value when holding data increases. This tendency has been reported to be significant especially when the trap count N is on the order of about 100 or less (see literature 2 “Gabriel Molas, Damien Deleruyelle, Barbara De Salvo, Gérard Ghibaudo, Marc Gély, Luca Perniola, Dominique Lafond, and Simon Deleonibus, “Degradation of Floating-Gate Memory Reliability by Few Electron Phenomena”, IEEE Trans. Electron Devices 53, 2610 (2006)”). That is, when the trap count N is on the order of about 100 or less, the data retention characteristic of the MONOS memory cell deteriorates.

To reduce the variation in data retention characteristic, therefore, the area S capable of holding the trap count N of the charge storage layer 62 at 100 or more is necessary. That is, expression (14) holds for the trap count N:

N=2πR₂L×Nₜᵣₐₚ>100 (14)

Expression (2) is obtained by setting Nₜᵣₐₚ at about 1×10¹³ cm⁻² in expression (14). In the MONOS memory cell according to this embodiment as described above, R₂ and L satisfy the relation of expression (2) described earlier in order to (b) reduce the variation in data retention characteristic.

### [Principle of (c) (Expression (3))]

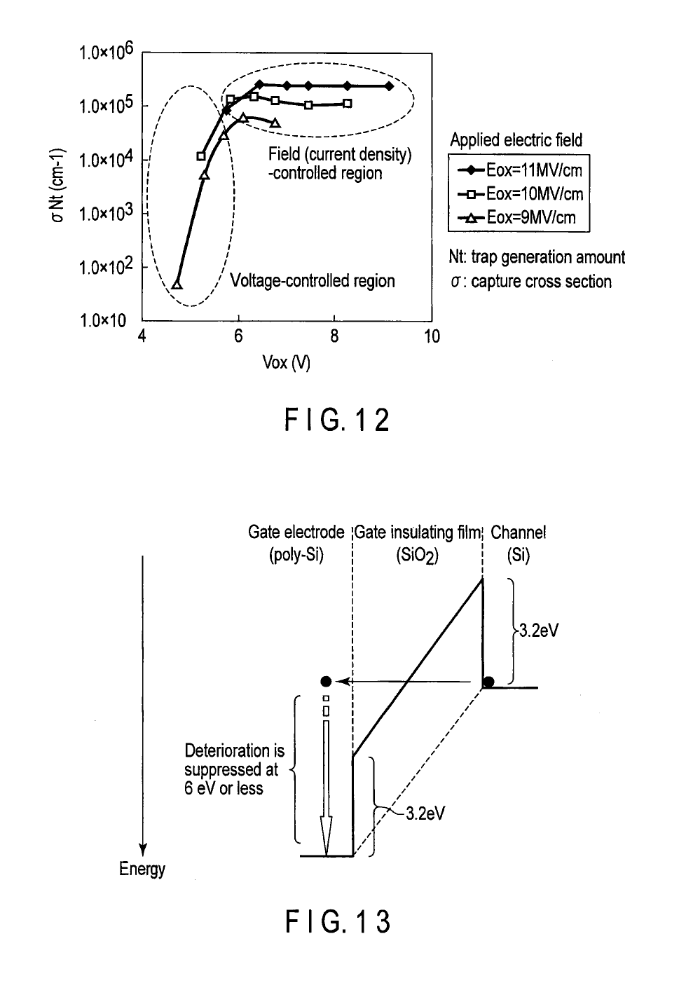

The principle of suppressing the deterioration of the data retention characteristic caused by repetitive write/erase of the MONOS memory cell according to this embodiment will be explained below with reference to FIGS. 12, 13, and 14. Note that the principle of (c) similarly applies to the first and second structures, so the following explanation does not particularly distinguish between them.

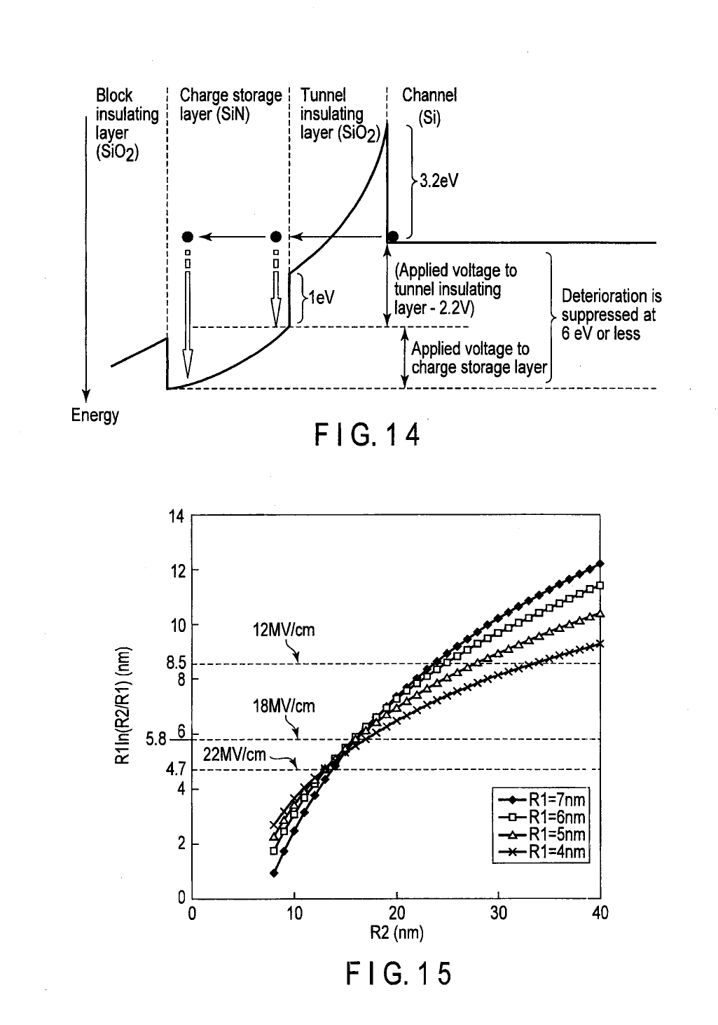

FIG. 12 is a graph showing the relationship between an applied voltage Vₒₓ and trap generation amount Nₜ in a silicon oxide monolayered film relevant to this embodiment. FIG. 13 is a view showing an energy band when a voltage is applied to a MOS transistor relevant to this embodiment. FIG. 14 is a view showing an energy band when a voltage is applied to the MONOS memory cell according to this embodiment.

Note that FIG. 13 shows a case in which a silicon oxide monolayered film is used as a gate insulating film of the MOS transistor. Note also that FIG. 14 shows a case in which silicon oxide is used as the tunnel insulating layer 63 of the MONOS memory cell, silicon nitride is used as the charge storage layer 62, and silicon oxide is used as the block insulating layer 61.

First, the MOS transistor using a silicon oxide monolayered film as the gate insulating film will be described. In the MOS transistor, a leakage current is generated when the thickness of the silicon oxide monolayered film is decreased to approximately 9 nm or less and a high electric field is applied. This leakage current is called a SILC (Stress-Induced Leakage Current). The SILC depends on the thickness of the silicon oxide monolayered film. More specifically, the SILC drastically increases when the thickness of the silicon oxide monolayered film decreases. On the other hand, the SILC reduces when the electric field to be applied to the silicon oxide monolayered film is decreased to about 9 MV/cm (literature 3 “N. K. Patel and A. Toriumi, “Stress-induced leakage current in ultrathin SiO₂ films”, Appl. Phys. Lett. 64, 1809 (1994)”).

These tendencies will be explained from the viewpoint of trap generation in the silicon oxide monolayered film. As shown in FIG. 12, the trap generation amount Nₜ in the silicon oxide monolayered film depends on only an applied electric field Eₒₓ when the applied voltage Vₒₓ to the silicon oxide monolayered film is 6 V or more (field-controlled), and depends on the applied voltage Vₒₓ when it is 6 V or less (voltage-controlled). Also, when the applied voltage Vₒₓ is 6 V or less, the trap generation amount Nₜ reduces exponentially with respect to the applied voltage Vₒₓ.

These results indicate that in the MOS transistor using the silicon oxide monolayered film as the gate insulating film, an electron energy of 6 eV at the anode terminal (gate electrode) is the threshold energy of the generation of electron-positive hole pairs that contribute to trap generation. That is, when the applied voltage Vₒₓ to the silicon oxide monolayered film is 6 V or more, traps are generated together with positive holes (anode holes), and the reliability deteriorates. In other words, the reliability can be assured by setting the applied voltage Vₒₓ to the silicon oxide monolayered film at 6 V or less.

The contents described above will be explained below with reference to FIG. 13 showing the relationship between the energy loss of electrons and an externally applied voltage in the MOS transistor. In the MOS transistor, the conduction band offset between the channel and gate insulating film is 3.2 eV, and that between the gate electrode and gate insulating film is also 3.2 eV. Therefore, the potential energy gained by electrons while they are passing through the gate insulating film is equal to the voltage to be applied to the gate insulating film. In this state, if electrons lose an energy of 6 eV (gain a potential energy of 6 V), traps (positive holes) are generated, and the reliability deteriorates.

The MONOS memory cell will now be explained based on the above-mentioned principle of the MOS transistor. In the MOS transistor, the energy of injected electrons is lost in the gate electrode. By contrast, when the charge trapping efficiency is high in the MONOS memory cell as shown in FIG. 14, the energy of injected electrons is lost in the tunnel insulating layer 63 (silicon oxide) and charge storage layer 62 (silicon nitride). According to more detailed analysis, when the thickness of the charge storage layer 62 is as small as about 5 nm, trapped electrons exist in the interface between the charge storage layer 62 and block insulating layer 61 (see literature 4 “Shosuke Fujii, Naoki Yasuda, Jun Fujiki, and Kouichi Muraoka, “A New Method to Extract the Charge Centroid in the Program Operation of Metal-Oxide-Nitride-Oxide-Semiconductor Memories”, Japanese Journal of Applied Physics 49, 04DD06 (2010)”). In the MONOS memory cell, therefore, the energy of injected electrons is mainly lost in the interface between the charge storage layer 62 and block insulating layer 61.

Also, in the MONOS memory cell, the conduction band offset between the channel and tunnel insulating layer 63 is 3.2 eV, whereas that between the tunnel insulating layer 63 and charge storage layer 62 is 1 eV. Accordingly, the potential energy gained by electrons immediately after they passed through the tunnel insulating layer 63 is represented by [applied voltage to tunnel insulating layer 63—2.2 V].

This is so because the conduction band offset between the tunnel insulating layer 63 and charge storage layer 62 in the MONOS memory cell is 1 eV, i.e., lower by 2.2 eV than 3.2 eV as the conduction band offset between the gate insulating film and gate electrode in the MOS transistor. That is, the conduction band edge (on the side of the charge storage layer 62) at the interface between the tunnel insulating layer 63 and charge storage layer 62 in the MONOS memory cell is raised by 2.2 eV, in comparison with the conduction band edge (on the gate electrode side) at the interface between the gate insulating film and the gate electrode in the MOS transistor. Note that the energy gained by electrons is measured from the conduction band edge. In the MONOS memory cell, therefore, the gained electron energy decreases by the rise of the conduction band edge, with the applied voltage to the tunnel insulating layer 63 as a reference.

Since the energy loss of injected electrons occurs at the interface between the charge storage layer 62 and block insulating layer 61, it is necessary to obtain the electron energy at this interface. The electron energy at this interface is obtained by adding the above-described applied voltage of the charge storage layer 62 to the above-described potential energy gained by electrons immediately after they passed through the tunnel insulating layer 63. That is, the potential energy finally gained by electrons is represented by [(applied voltage to tunnel insulating layer 63—2.2 V)+(applied voltage to charge storage layer 62)].

To suppress the deterioration of the reliability (the deterioration of the charge retention characteristic caused by cycling), it is necessary to satisfy [(applied voltage to tunnel insulating layer 63—2.2 V)+(applied voltage to charge storage Layer 62)]<6 V. This condition is represented by expression (15) by using an applied voltage V_{R1R2} to the tunnel insulating layer 63 and charge storage layer 62, R₁, and R₂:

$${V}_{{R}_{1} {R}_{2}} = {\int }_{{R}_{1}}^{{R}_{2}} E d r = \frac{{ɛ}_{Si O 2}}{{ɛ}_{ave}} {E}_{tunnel} {R}_{1} ln ( \frac{{R}_{2}}{{R}_{1}} ) < 8.2 [ V ] \qquad ( 15 )$$

where ∈ₐᵥₑ is the average dielectric constant of the tunnel insulating layer 63 and charge storage layer 62. ∈ₐᵥₑ is about 5 when the charge storage layer 62 is made of silicon nitride and the thicknesses of the tunnel insulating layer 63 and charge storage layer 62 are almost equal. ∈SiO₂ indicates the dielectric constant of silicon oxide, and is about 3.9. Eₜᵤₙₙₑₗ indicates the applied electric field to the tunnel insulating layer 63. Eₜᵤₙₙₑₗ is about 12 MV/cm (inclusive) to 22 MV/cm (inclusive) in a typical memory cell operation. This lower limit (12 MV/cm) is a condition under which write/erase operations are possible. The upper limit (22 MV/cm) is a condition determined by the breakdown voltage of the tunnel insulating layer 63.

Expression (3) is obtained for R₁ and R₂ from the upper and lower limits of Eₜᵤₙₙₑₗ and expression (15). Thus, R₁ and R₂ must satisfy the above-mentioned relation of expression (3) in order to (c) suppress the deterioration of the data retention characteristic caused by repetitive write/erase by controlling the electron energy in the MONOS memory cell according to this embodiment.

Note that the above explanation has been made in a case in which the charge storage layer 62 is made of silicon nitride. When the charge storage layer 62 is made of a material other than silicon nitride, however, the above-described condition for suppressing the deterioration of the charge retention characteristic caused by cycling can be different. When the charge storage layer 62 is made of a material other than silicon nitride, [(applied voltage to tunnel insulating layer 63—φ_{charge})+(applied voltage to charge storage layer 62)]<6 V is satisfied in order to suppress the deterioration of the charge retention characteristic caused by cycling. That is, 2.2 V (the conduction band offset between silicon and silicon nitride) when the charge storage layer 62 is silicon nitride is replaced with φ_{charge} (the conduction band offset between silicon and the material of the charge storage layer 62). This makes it possible to suppress the deterioration of the charge retention characteristic caused by cycling even when the charge storage layer 62 is made of a material other than silicon nitride.

### EXAMPLES

Examples 1 and 2 of the MONOS memory cell according to this embodiment will be explained below with reference to FIGS. 15, 16, and 17.

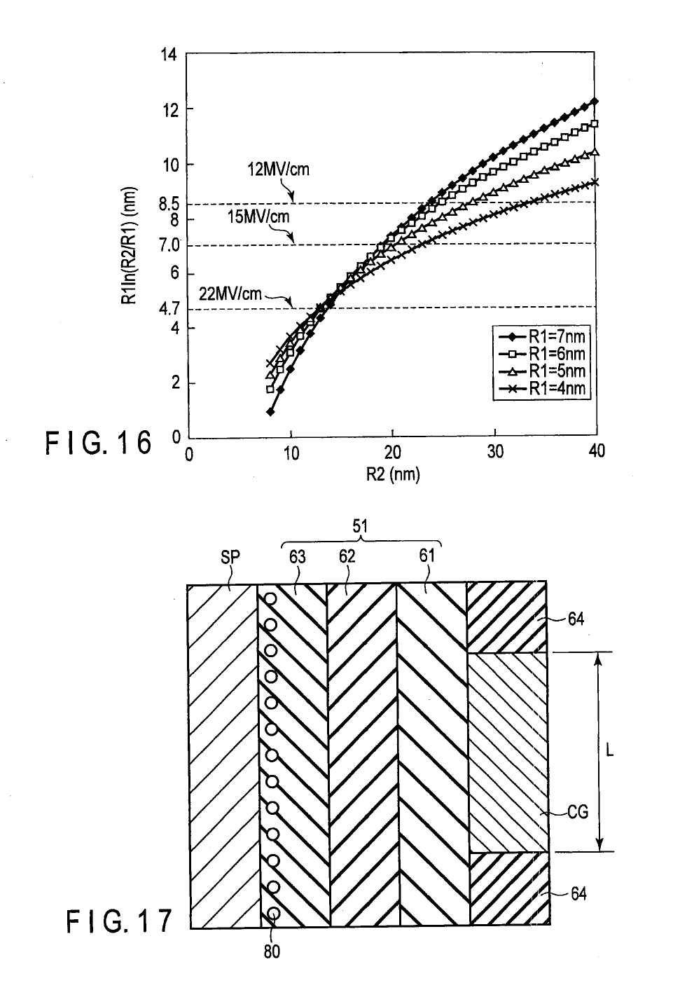

FIG. 15 is a graph showing the relationship between R₁ ln(R₂/R₁) and R₂ of the MONOS memory cell according to this embodiment, and shows Example 1. FIG. 16 is a graph showing the relationship between R₁ ln(R₂/R₁) and R₂ of the MONOS memory cell according to this embodiment, and shows Example 2. FIG. 17 is an enlarged sectional view of Example 2 of the MONOS memory cell according to this embodiment.

In Example 1, L=20 nm, R₁=7 nm, R₂=15 nm, and R₃=27 nm are defined as examples satisfying expressions (1) to (3) of the first structure and expressions (2) to (4) of the second structure. These values are determined as follows.

First, the thickness L of the control gate CG is set in accordance with the generation of the memory. In this example, L is, e.g., 20 nm. Consequently, R₂>8 nm from expression (2).

Next, an operating electric field (an applied electric field to the tunnel insulating layer 63) is set. As described above, this operating electric field is set at 12 MV/cm (inclusive) to 22 MV/cm (inclusive). By thus setting the operating electric field, R₁ ln(R₂/R₁) is uniquely determined as shown in FIG. 15. That is, the relationship between R₁ and R₂ is determined by setting the operating electric field. In this example, the operating electric field is set at, e.g., 18 MV/cm. Consequently, R₁ ln(R₂/R₁)=5.8 nm as shown in FIG. 15.

After that, R₁=7 nm and R₂=15 nm, for example, are so set as to satisfy R₂>8 nm and R₁ ln(R₂/R₁) 5.8 nm.

R₃ is appropriately set in the first and second structures. In the first structure, R₃/7>1.4 from expression (1). To meet this condition, R₃=27 nm is set by, e.g., setting the thickness of the block insulating layer 61 to 12 nm. In the second structure, R₃/7>1.8 from expression (4). To meet this condition, R₃=27 nm is set by, e.g., setting the thickness of the block insulating layer 61 to 12 nm (10 nm for the first layer 72 and 2 nm for the cap layer 71).

In Example 2, L=10 nm, R₁=7 nm, R₂=19 nm, and R₃=30 nm are defined as examples satisfying expressions (1) to (3) of the first structure and expressions (2) to (4) of the second structure. These values are determined as follows.

First, the thickness L of the control gate CG is set in accordance with the generation of the memory. In this example, L is smaller than that of Example 1, e.g., 10 nm. Consequently, R₂>16 nm from expression (2).

Next, an operating electric field (an applied electric field to the tunnel insulating layer 63) is set. As described above, this operating electric field is set at 12 MV/cm (inclusive) to 22 MV/cm (inclusive). By thus setting the operating electric field, R₁ ln(R₂/R₁) is uniquely determined as shown in FIG. 16. That is, the relationship between R₁ and R₂ is determined by setting the operating electric field.

In Example 2, as shown in FIG. 17, silicon microcrystals 80 are added to the tunnel insulating layer 63. The silicon microcrystals 80 are desirably distributed at an equal density in the tunnel insulating layer 63, but the present embodiment is not limited to this. Since the tunnel insulating layer 63 contains the silicon microcrystals 80, the operating electric field can be reduced by about 15% from that of Example 1. In Example 2, therefore, the operating electric field is set at, e.g., 15 MV/cm. Consequently, R₁ ln(R₂/R₁)=7.0 nm as shown in FIG. 16.

After that, R₁=7 nm and R₂=19 nm, for example, are so set as to satisfy R₂>16 nm and R₁ ln(R₂/R₁)=7.0 nm.

R₃ is appropriately set in the first and second structures. In the first structure, R₃/7>1.4 from expression (1). To meet this condition, R₃=30 nm is set by, e.g., setting the thickness of the block insulating layer 61 to 11 nm. In the second structure, R₃/7>1.8 from expression (4). To meet this condition, R₃=30 nm is set by, e.g., setting the thickness of the block insulating layer 61 to 11 nm (9 nm for the first layer 72 and 2 nm for the cap layer 71).

As described above, Examples 1 and 2 have been explained as examples of the definitions of L, R₁, R₂, and R₃, but the present embodiment is not limited to these examples. It is possible to appropriately set these values so as to satisfy expressions (1) to (3) in the first structure, and expressions (2) to (4) in the second structure.

Note that when the planar shape of the memory hole is not a true circle (e.g., when it is an ellipse), the average values of R₁, R₂, and R₃ in one memory hole are used as their values. Also, if the radii of memory holes vary, the average values of all the memory holes are used as R₁, R₂, and R₃. The values of R₁, R₂, and R₃ thus obtained are so set as to satisfy expressions (1) to (3) in the first structure, and expressions (2) to (4) in the second structure.

### <Effects>

According to the above-mentioned embodiments, in the cylindrical three-dimensionally stacked MONOS memory, the radius of the memory hole and the various thicknesses are so set as to satisfy expressions (1) to (3) in the first structure, and expressions (2) to (4) in the second structure. This makes it possible to (a) secure the erase characteristic, (b) reduce the variation in data retention characteristic, and (c) suppress the deterioration of the data retention characteristic caused by repetitive write/erase.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile semiconductor memory device comprising:
a semiconductor substrate;
conductive layers and insulating layers alternately stacked above the semiconductor substrate;
a block insulating layer which is formed on an inner surface of a hole formed in the conductive layers and the insulating layers and extending in a stacking direction, and has a silicon oxide interface with respect to the conductive layers;
a charge storage layer formed on the block insulating layer;
a tunnel insulating layer formed on the charge storage layer; and
a semiconductor layer formed on the tunnel insulating layer,
wherein letting R₁ be a distance from a central axis of the hole to an interface between the semiconductor layer and the tunnel insulating layer, R₂ be a distance from the central axis of the hole to an interface between the charge storage layer and the block insulating layer, R₃ be a distance from the central axis of the hole to the interface between the block insulating layer and the conductive layers, and L be a thickness of the conductive layers in the stacking direction, expressions (1) to (3) below hold:
$$\begin{matrix}\frac{{R}_{3}}{{R}_{1}} > 1.4 & ( 1 ) \\ {R}_{2} L > 1.6 \times {10}^{- 12} [ {cm}^{2} ] & ( 2 ) \\ 4.8 [ nm ] < {R}_{1} ln ( \frac{{R}_{2}}{{R}_{1}} ) < 8.8 [ nm ] & ( 3 )\end{matrix}$$

2. The device of claim 1, wherein the charge storage layer includes silicon nitride, and the tunnel insulating layer includes silicon oxide.

3. The device of claim 1, wherein the tunnel insulating layer contains a silicon microcrystal.

4. The device of claim 1, wherein 60 nm≧R₃>R₂>R₁>0.

5. The device of claim 1, wherein the block insulating layer is formed by a multilayered film containing silicon oxide, silicon nitride, and silicon oxide formed in this order on the conductive layers.

6. The device of claim 1, wherein the block insulating layer is formed by a silicon oxide monolayered film formed on the conductive layers.

7. A nonvolatile semiconductor memory device comprising:
a semiconductor substrate;
conductive layers and insulating layers alternately stacked above the semiconductor substrate;
a block insulating layer which is formed on an inner surface of a hole formed in the conductive layers and the insulating layers and extending in a stacking direction, and has a silicon nitride interface with respect to the conductive layers;
a charge storage layer formed on the block insulating layer;
a tunnel insulating layer formed on the charge storage layer; and
a semiconductor layer formed on the tunnel insulating layer,
wherein letting R₁ be a distance from a central axis of the hole to an interface between the semiconductor layer and the tunnel insulating layer, R₂ be a distance from the central axis of the hole to an interface between the charge storage layer and the block insulating layer, R₃ be a distance from the central axis of the hole to the interface between the block insulating layer and the conductive layer, and L be a thickness of the conductive layer in the stacking direction, expressions (2) to (4) below hold:
$$\begin{matrix}{R}_{2} L > 1.6 \times {10}^{- 12} [ {cm}^{2} ] & ( 2 ) \\ 4.8 [ nm ] < {R}_{1} ln ( \frac{{R}_{2}}{{R}_{1}} ) < 8.8 [ nm ] & ( 3 ) \\ \frac{{R}_{3}}{{R}_{1}} > 1.8 & ( 4 )\end{matrix}$$

8. The device of claim 7, wherein the charge storage layer includes silicon nitride, and the tunnel insulating layer includes silicon oxide.

9. The device of claim 7, wherein the tunnel insulating layer contains a silicon microcrystal.

10. The device of claim 7, wherein 60 nm≧R₃>R₂>R₁>0.

11. The device of claim 7, wherein the block insulating layer comprises a cap layer formed on the conductive layers and containing silicon nitride, and a first layer formed by a multilayered film containing silicon oxide, silicon nitride, and silicon oxide formed in this order on the cap layer.

12. The device of claim 7, wherein the block insulating layer comprises a cap layer formed on the conductive layers and containing silicon nitride, and a monolayered film formed on the cap layer and containing silicon oxide.

13. A nonvolatile semiconductor memory device comprising:
a semiconductor substrate;
conductive layers and insulating layers alternately stacked above the semiconductor substrate;
a block insulating layer which is formed on an inner surface of a hole formed in the conductive layers and the insulating layers and extending in a stacking direction;
a charge storage layer formed on the block insulating layer;
a tunnel insulating layer formed on the charge storage layer; and
a semiconductor layer formed on the tunnel insulating layer,
wherein letting R₁ be a distance from a central axis of the hole to an interface between the semiconductor layer and the tunnel insulating layer, and R₂ be a distance from the central axis of the hole to an interface between the charge storage layer and the block insulating layer, an expression (3) below holds:
$$4.8 [ nm ] < {R}_{1} ln ( \frac{{R}_{2}}{{R}_{1}} ) < 8.8 [ nm ] \qquad ( 3 )$$

14. The device of claim 13, wherein the charge storage layer includes silicon nitride, and the tunnel insulating layer includes silicon oxide.

15. The device of claim 13, wherein the tunnel insulating layer contains a silicon microcrystal.

16. The device of claim 13, wherein
the block insulating layer has a silicon oxide interface with respect to the conductive layers, and
letting R₃ be a distance from the central axis of the hole to the interface between the block insulating layer and the conductive layer, expression (1) below holds:
$$\frac{{R}_{3}}{{R}_{1}} > 1.4 \qquad ( 1 )$$

17. The device of claim 16, wherein the block insulating layer is formed by a multilayered film containing silicon oxide, silicon nitride, and silicon oxide formed in this order on the conductive layers.

18. The device of claim 13, wherein
the block insulating layer has a silicon nitride interface with respect to the conductive layers, and
letting R₃ be a distance from the central axis of the hole to the interface between the block insulating layer and the conductive layer, expression (4) below holds:
$$\frac{{R}_{3}}{{R}_{1}} > 1.8 \qquad ( 4 )$$

19. The device of claim 18, wherein the block insulating layer comprises a cap layer formed on the conductive layers and containing silicon nitride, and a first layer formed by a multilayered film containing silicon oxide, silicon nitride, and silicon oxide formed in this order on the cap layer.

20. The device of claim 13, wherein letting L be a thickness of the conductive layer in the stacking direction, expression (2) below holds:
R₂L>1.6×10⁻¹²[cm²] (2)
